(19) United States
(12) Patent Application Publication
(10) Pub. No.: US 2025/0125158 A1
(43) Pub. Date: Apr. 17, 2025

(54) METHOD FOR ATTACHING A HEAT SPREADER TO A SEMICONDUCTOR PACKAGE AND SEMICONDUCTOR PACKAGE ASSEMBLIES

(71) Applicant: STATS ChipPAC Pte. Ltd, Singapore (SG)

(72) Inventors: YongHyuk JEONG, Incheon (KR); JinHee JUNG, Incheon (KR); GwangTae KIM, Incheon (KR)

(21) Appl. No.: 18/914,058

(22) Filed: Oct. 12, 2024

(30) Foreign Application Priority Data
Oct. 16, 2023 (CN) 202311336465X

(51) Int. Cl. H01L 21/56; H01L 21/48; H01L 23/00; H01L 23/31; H01L 23/373

(52) U.S. Cl. CPC H01L 21/565; H01L 21/4882; H01L 23/315; H01L 23/3736; H01L 24/32; H01L 2224/32245

(57) ABSTRACT

A method for attaching a heat spreader to a semiconductor package is provided. The method comprises: providing a semiconductor package, wherein the semiconductor package comprises a package substrate, a semiconductor component mounted on the package substrate and a mold cap formed on the package substrate and encapsulating the semiconductor component, and wherein the mold cap comprises a laser-activatable mold compound; removing a portion of a thickness of the mold cap above the semiconductor component by laser ablation to form a cavity in the mold cap and transform the laser-activatable mold compound at an inner surface of the cavity to a conductive layer; dispensing a thermal interface material (TIM) in the cavity to form on the conductive layer a TIM layer that protrudes from the mold cap; and attaching the heater spreader to the semiconductor package at least through the TIM layer.

### TECHNICAL FIELD

The present application generally relates to semiconductor technologies, and more particularly, to a method for attaching a heat spreader to a semiconductor package and semiconductor package assemblies.

### BACKGROUND OF THE INVENTION

Mold caps are generally used in semiconductor packages to protect semiconductor chips from external damages and contaminations. However, due to the low thermal conductivity of mold materials of the mold caps, heat cannot be well dissipated from the semiconductor chips to the external environment. Therefore, a thermal interface material (TIM) layer is applied on an outer surface of the mold cap to facilitate heat dissipation.

FIG. 1 illustrates a conventional semiconductor package assembly 10 which assemblies a semiconductor package 12 with a heat spreader 14. A TIM layer 16 is formed between the semiconductor package 12 with a heat spreader 14 to facilitate heat dissipation. Furthermore, a seed layer 17 is plated or sputtered on a mold cap 18 and a semiconductor component 19 of the semiconductor package 12 to allow for the formation of the TIM layer 16. The plating of the seed layer 17 introduces additional processing that increases the manufacturing cost of the semiconductor package assembly 10. Also, there is a risk that the semiconductor component 19 may crack due to external damages applied during a grinding process for the mold cap 18, and delamination may occur between the surface of the semiconductor component 19 and the mold cap 18 and the TIM layer 16.

FIG. 2 illustrates another conventional semiconductor package assembly 20 which assemblies a semiconductor package 22 with a heat spreader 24. A TIM layer 26 may be formed between the semiconductor package 22 and the heat spreader 24. However, there may be a risk of pumping out of the TIM material 26, and voids 28 may be formed in the TIM layer 26, which may deteriorate heat dissipation from the semiconductor package 22 to the heat spreader 24. Also, the TIM material 26 may not be well controlled in shape so that it may flow onto certain component such as a resistor 29 of the semiconductor package 22, resulting in shortage and electrical failure of the semiconductor package assembly 20. Furthermore, a semiconductor component of the semiconductor package 22 may crack due to external pressure and stress applied by the nonuniform TIM material 26.

Therefore, a need exists for further improvement to the methods for attaching heat spreaders to semiconductor packages.

### SUMMARY OF THE INVENTION

An objective of the present application is to provide a method for attaching a heat spreader to a semiconductor package with improved crack prevention.

According to an aspect of the present application, a method for attaching a heat spreader to a semiconductor package is provided. The method comprises: providing a semiconductor package, wherein the semiconductor package comprises a package substrate, a semiconductor component mounted on the package substrate and a mold cap formed on the package substrate and encapsulating the semiconductor component, and wherein the mold cap comprises a laser-activatable mold compound; removing a portion of a thickness of the mold cap above the semiconductor component by laser ablation to form a cavity in the mold cap and transform the laser-activatable mold compound at an inner surface of the cavity to a conductive layer; dispensing a thermal interface material (TIM) in the cavity to form on the conductive layer a TIM layer that protrudes from the mold cap; and attaching the heater spreader to the semiconductor package at least through the TIM layer.

According to another aspect of the present application, a semiconductor package assembly is provided. The semiconductor package assembly comprises: a semiconductor package, wherein the semiconductor package comprises: a package substrate, a semiconductor component mounted on the package substrate, and a mold cap formed on the package substrate and encapsulating the semiconductor component, wherein the mold cap comprises a laser-activatable mold compound, the mold cap comprises a cavity formed above the semiconductor component and having a conductive layer at its inter surface, and the cavity and the conductive layer are formed by laser ablation of the laser-activatable mold compound; a thermal interface material (TIM) layer formed in the cavity of the mold cap and protruding from the mold cap; and a heater spreader attached to the semiconductor package at least through the TIM layer.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 illustrates a conventional semiconductor package assembly which assemblies a semiconductor package with a heat spreader.

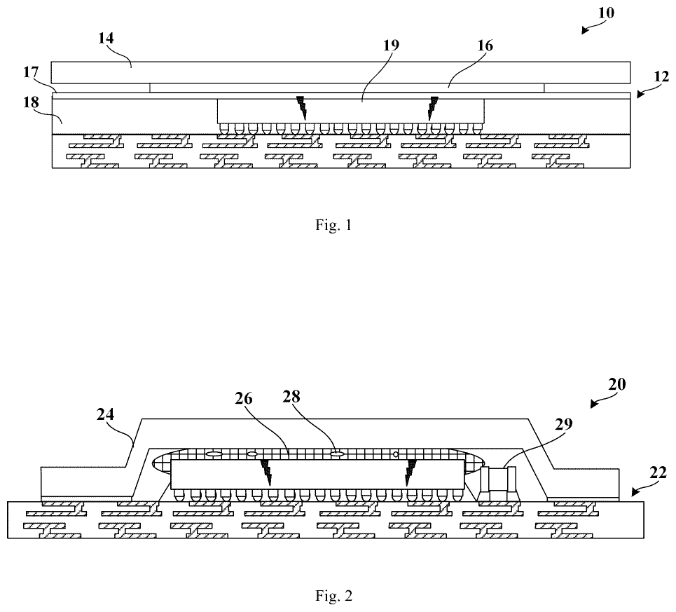

FIG. 2 illustrates another conventional semiconductor package assembly which assemblies a semiconductor package with a heat spreader.

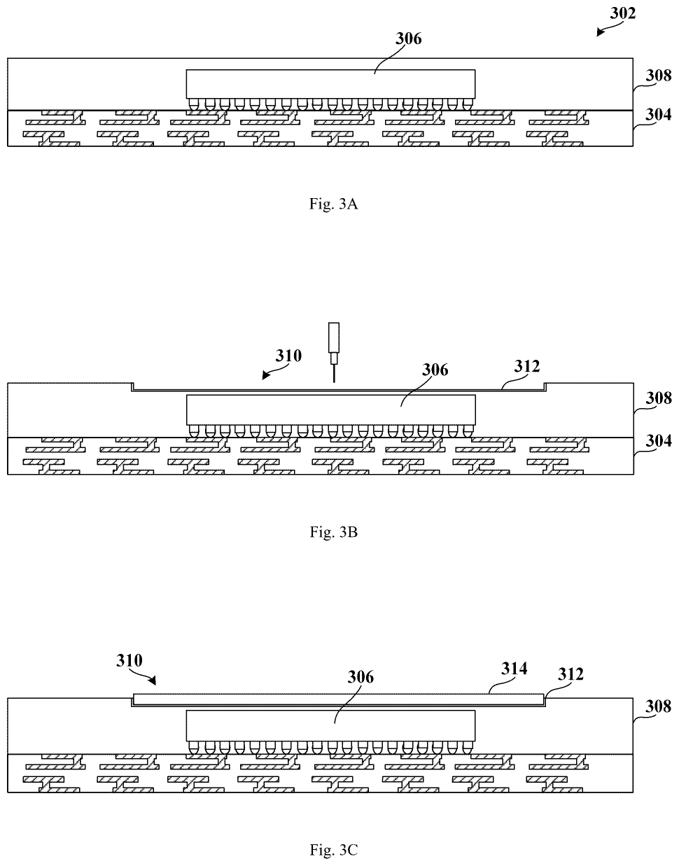

FIGS. 3A to 3D illustrate a method for attaching a heat spreader to a semiconductor package according to an embodiment of the present application.

FIG. 3E illustrates an enlarged view of a portion of a conductive layer shown in FIG. 3B.

FIGS. 4A to 4E illustrate a method for attaching a heat spreader to a semiconductor package according to another embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As aforementioned, conventional heat spreader attaching methods are complicated in processing and may produce cracks or voids due to external stress applied during the attaching process. To address at least one of these issues, the inventors of the present application have conceived a method of using certain type of laser-activatable mold compound to encapsulate semiconductor components under a heat spreader. The laser-activatable mold compound can be removed and activated by laser, resulting in an easy manner to form a cavity coated with a seed layer for a thermal interface material (TIM) layer. In this way, the entire attaching process can be simplified significantly.

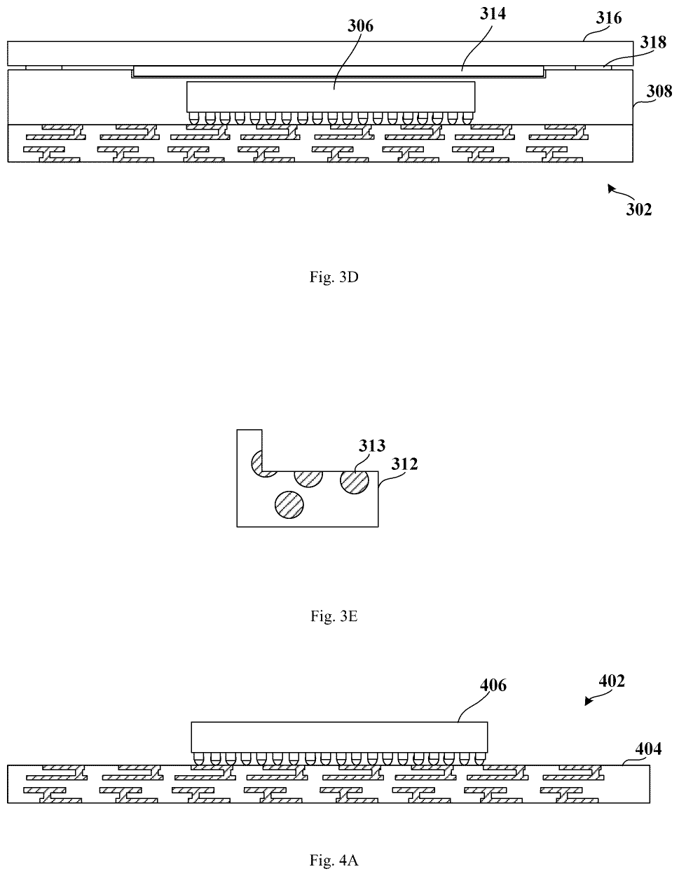

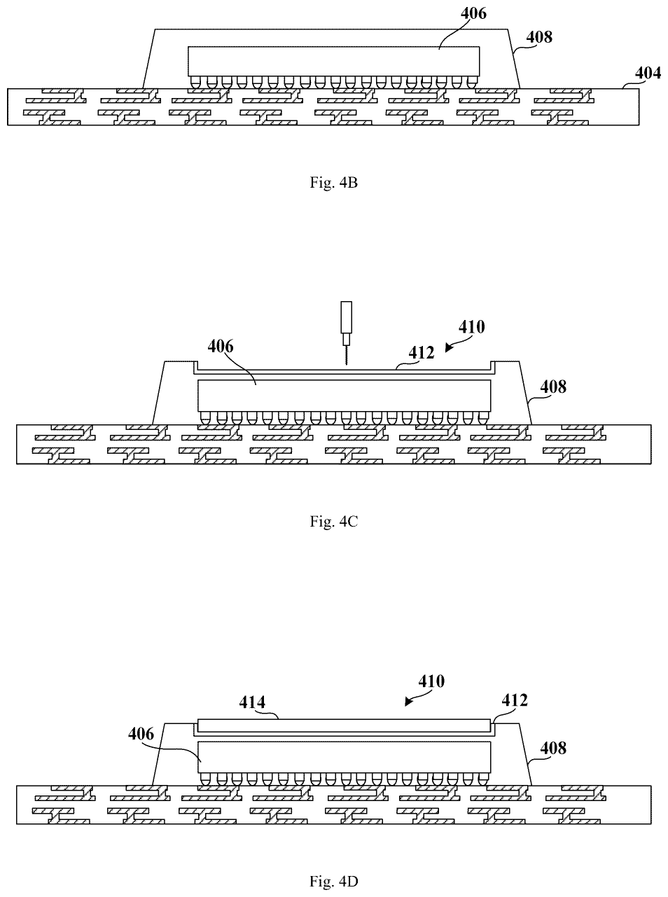

FIGS. 3A to 3D illustrate a method for attaching a heat spreader to a semiconductor package according to an embodiment of the present application. In the embodiment, the semiconductor package is a strip type package that can be singulated from a semiconductor package strip, which may include a row of semiconductor packages, or two or more rows of semiconductor packages. It can be appreciated that the embodiment shown in FIGS. 3A to 3D only illustrate one semiconductor package, however, the other semiconductor packages formed on a semiconductor package strip may be processed similarly.

As shown in FIG. 3A, a semiconductor package 302 is provided. The semiconductor package 302 includes a package substrate 304, and a semiconductor component 306 mounted on the package substrate 304. By way of example, the package substrate 304 can include a printed circuit board (PCB), a carrier substrate, a semiconductor substrate with electrical interconnections, or a ceramic substrate. In some other examples, the package substrate 304 may include a laminate interposer, a strip interposer, a leadframe, or other suitable substrates. In particular, the package substrate 304 may include one or more insulating or passivation layers, one or more conductive vias formed through the insulating layers, and one or more conductive layers formed over or between the insulating layers. The conductive vias and conductive layers form together various interconnect structures in the package substrate 304. Furthermore, the interconnect structures may include one or more sets of conductive patterns which are exposed from a front surface of the package substrate 304. For example, the conductive patterns may take the form of contact pads or other similar structures. Each set of conductive patterns may be used to establish electrical connection with an electronic component such as the semiconductor component 306 disposed on the package substrate 304. In some embodiments, the semiconductor component 306 may be a semiconductor chip with an exposed surface of a semiconductor material, which is relatively fragile, in some other embodiments, the semiconductor component 306 may be a semiconductor package that is encapsulated with an encapsulant layer.

A mold cap 308 is formed on the package substrate 304, and may encapsulate the semiconductor component 306 on the package substrate 304. In some embodiments, the mold cap 308 may be made, partially or in all, of a polymer composite material such as epoxy resin with filler, epoxy acrylate with filler, or polymer with proper filler. The mold cap 308 can protect the semiconductor component 306 from external environment and damages. In the embodiment, the mold cap 308 includes at least in its upper portion a laser-activatable mold compound, or may include in its entirety the laser-activatable mold compound. For example, the laser-activatable mold compound may include a base material such as the aforementioned polymer composite material, and additives which are activatable by laser. The additives which are generally formed of metal particles can be opened by laser to exhibit electrical conductivity. In some examples, the mold cap 308 can be a laser direct structuring material layer. The laser direct structuring material layer refers to a material layer for implementing a process of selective metallization of defined regions after impingement of laser irradiation “activation” on a substrate containing additives, which release metal “seeds” capable of promoting the metal deposition to form a conductive pathway. In a laser direct structuring process, a laser beam travels over the molded article to activate the surface at locations where a conductive metal path is desired, thus, “structuring” the article. Furthermore, the base material of the mold cap 308 which is generally a polymer composite material can be removed by laser ablation, and thus the mold cap 308 can be patterned as desired, as will be elaborated below.

In the embodiment shown in FIG. 3A, the mold cap 308 is formed of a layer of laser-activatable mold compound, however, in some alternative embodiments, the mold cap 308 may be formed of two or more layers of mold compounds, including a top layer of laser-activatable mold compound and other underneath layers of non-laser-activatable mold compounds. Furthermore, the mold cap 308 has a top surface that is above a top surface of the semiconductor component 306, such that a thickness of the mold cap 308 above the semiconductor component 306 can be used for the formation of the seed layer for the TIM layer. In some examples, the thickness of the mold cap 308 above the semiconductor component 306 may be tens of microns to hundreds or even thousands of microns.

Next, as shown in FIG. 3B, a laser beam may be directed to the top surface of the mold cap 308, or in particular to a region directly above the semiconductor component 306. Initially, the laser beam may have an intensity that is sufficient to ablate a portion of the mold cap 308 and form a cavity 310 in the mold cap 308. The cavity 310 may remove a portion of the thickness of the mold cap 308 above the semiconductor component 306, but maintain a remaining portion of the mold cap 308 covering the semiconductor component 306. The remaining portion of the mold cap 308 may have a thickness of 0.5 micron to 20 microns, or preferably 1 micron to 5 microns, which can protect the top surface of the semiconductor component 306 from potential damages in the subsequent processes.

The cavity 310 in the mold cap 306 is formed to accommodate the TIM material for a heat spreader (not shown). Thus, a depth of the cavity 310 depends on an amount of the TIM material to be filled therein. In some embodiments, the depth of the cavity 310 may range from 5 microns to 500 microns or even greater. Furthermore, in some preferred embodiments, the cavity 310 in the mold cap 308 may extend across an entirety of the semiconductor component 306, that is, a projection of the semiconductor component 306 onto the package substrate 304 may be fully within a projection of the cavity 310 onto the package substrate 304. In this way, a better thermal path may be formed through the TIM material filled in the cavity 310.

After the cavity 310 is formed, the laser beam may be adjusted, for example, in its intensity. The adjusted laser beam may not further ablate or remove the mold compound of the mold cap 306, but is sufficient to transform the laser-activatable mold compound at an inner surface of the cavity 310 to a conductive layer 312. As aforementioned, after being activated, the laser-activatable mold compound may release metal “seeds” capable of promoting metal deposition to form a conductive pathway. Referring to FIG. 3E, an enlarged view of a portion of the conductive layer 312 is illustrated. The metal particles 313, which are distributed within the conductive layer 312, may be opened by the laser irradiation to break their outer shells and expose their interior metal cores. In some embodiments, the conductive layer 312 may have a thickness of 100 nanometers to 10 microns, or preferably 200 nanometers to 2 microns.

Next, as shown in FIG. 3C, a TIM material may be dispensed in the cavity 310 of the mold cap 308 to form on the conductive layer 312 a TIM layer 314. Due to the existence of the conductive layer 312, the TIM material can be easily attached to the mold cap 308 and deposited there. In some embodiments, the TIM layer 314 may protrude from the mold cap 308, that is, a top surface of the TIM layer 314 may be higher than the top surface of the mold cap 308. In this way, the cavity 310 can be fully filled by the TIM material, avoiding the formation of voids or other similar defects between the mold cap 308 and a heat spreader to be attached due to insufficiency of the TIM material.

The TIM layer 314 is used for enhancing thermal coupling between a heat-producing device and a heat dissipating device. Specifically speaking, at each contact interface, a thermal boundary resistance exists to impede heat dissipation, and electronic performance and device lifetime can degrade dramatically under continuous overheating and large thermal stress at the contact interfaces. The TIM layer 314 may reduce the thermal boundary resistance between layers, enhance thermal management performance, as well as tackle application requirements such as low thermal stress between materials of different thermal expansion coefficients, low clastic modulus or viscosity, flexibility, and reusability. In some embodiments, the TIM material can be thermally conductive, dispensable materials, preferably thermal greases, thermal adhesives, thermal gap fillers, liquid metal, and solder paste. In an embodiment, the TIM material is an epoxy compound, which may be used for easy bonding to metals, ceramics, most plastics and a wide variety of other materials. In another embodiment, the TIM material includes solder paste which has improved thermal conductivity over typical thermal interface material. Preferably, the solder paste is Ag—In solder alloy. Specifically, the TIM material may be a solder preform, that is, a solid, flat, manufactured-shape of solder, and a flux may be applied to coat the solder preform.

After the laser processing and TIM dispensing, a heat spreader 316 may be attached to the semiconductor package 302 through the TIM layer 314. The heat spreader 316 is generally made of high thermal conductive metallic materials for efficient heat dissipation. In the embodiment, the heat spreader 316 may function in combination with the TIM layer 314 to provide better heat dissipation for the semiconductor component 306. The heat spreader 316 is preferably made of copper, aluminum, and copper-tungsten alloy. It can be appreciated that other suitable materials can be used to form the heat spreader 316. Furthermore, although a portion of the mold compound of the mold cap 308 remains between the TIM layer 314 and the semiconductor component 306, the thickness of the remaining portion of mold compound is not significant, e.g., 0.5 micron to 20 microns. Therefore, the remaining portion of mold compound may generally not impede heat transfer from the semiconductor component 306 to the heat spreader 316.

It can be appreciated that the heat spreader 316 generally has a size that is greater than the TIM layer 314. Therefore, the heat spreader 316 may extend laterally from the TIM layer 314, as shown in FIG. 3D. Accordingly, various blocks of adhesive material 318 may be formed on the mold cap 308 not covered by the TIM layer 314, and filled in a gap between the heat spreader 316 and the mold cap 308. The adhesive material 318 can improve attachment of the heat spreader 316 to the semiconductor package 302, while not affecting the heat transfer from the semiconductor component 306 to the heat spreader 316.

After the various steps shown in FIGS. 3A to 3D, a semiconductor package assembly which combines a semiconductor package and a heat spreader can be obtained.

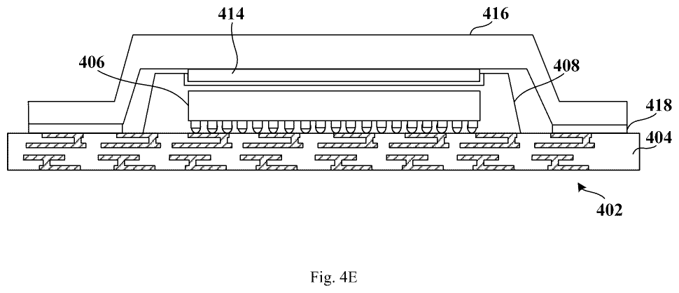

FIGS. 4A to 4E illustrate a method for attaching a heat spreader to a semiconductor package according to another embodiment of the present application. In the embodiment, the semiconductor package is a unit type package that has been singulated from a semiconductor package strip.

As shown in FIG. 4A, a semiconductor package 402 is provided. The semiconductor package 402 includes a package substrate 404 and a semiconductor component 406 mounted thereon. It can be appreciated that other components may be mounted on the package substrate 404.

Next, as shown in FIG. 4B, a mold cap 408 is formed on the package substrate 404, and may encapsulate the semiconductor component 406 on the package substrate 404. The mold cap 408 may be shaped and sized according to the semiconductor component 406. For example, in the embodiment shown in FIG. 4B, the mold cap 408 may be shaped as a truncated pyramid. However, in some other examples, the mold cap 408 may be shaped as a cuboid, a truncated cone, or any other suitable shape. In some embodiments, the mold cap 408 may be made, partially or in all, of a polymer composite material such as epoxy resin with filler, epoxy acrylate with filler, or polymer with proper filler. The base material of the mold cap 408 which is generally a polymer composite material can be removed by laser ablation, and thus the mold cap 408 can be patterned as desired, as will be elaborated below.

Furthermore, the mold cap 408 includes at least in its upper portion a laser-activatable mold compound. In some examples, the mold cap 408 can be a laser direct structuring material layer. The laser-activatable mold compound may include metal “seeds” capable of promoting the metal deposition to form a conductive pathway, i.e., serving as a seed layer for metal deposition. It can be appreciated that in some embodiments, the mold cap 408 may be made of the laser-activatable mold compound.

Next, as shown in FIG. 4C, a laser beam may be directed to the top surface of the mold cap 408, or in particular to a region directly above the semiconductor component 406. The laser beam may have an intensity that is sufficient to ablate a portion of the mold cap 408 and form a cavity 410 in the mold cap 408. The cavity 410 may remove a portion of the thickness of the mold cap 408 above the semiconductor component 406, but maintain a remaining portion of the mold cap 408 covering the semiconductor component 406. After the cavity 410 is formed, the intensity of the laser beam may be adjusted to avoid further ablation of the mold compound of the mold cap 406. However, the laser beam may be sufficient to transform the laser-activatable mold compound at an inner surface of the cavity 410 to a conductive layer 412, i.e., which later functions as the seed layer.

Next, as shown in FIG. 4D, a TIM material may be dispensed in the cavity 410 of the mold cap 408 to form on the conductive layer 412 a TIM layer 414. Due to the existence of the conductive layer 412, the TIM material can be easily attached to the mold cap 408 and deposited there. In some embodiments, the TIM layer 414 may protrude from the mold cap 408.

Next, as shown in FIG. 4E, a heat spreader 416 may be attached to the semiconductor package 402 through the TIM layer 414. The heat spreader 416 may function in combination with the TIM layer 414 to provide better heat dissipation for the semiconductor component 406. Although a portion of the mold compound of the mold cap 408 remains between the TIM layer 414 and the semiconductor component 406, the thickness of the remaining portion of mold compound is not significant, e.g., 0.5 micron to 20 microns. Therefore, the remaining portion of mold compound may generally not impede heat transfer from the semiconductor component 406 to the heat spreader 416.

Since the semiconductor component 406 and the mold cap 408 may occupy only a portion of the footprint on the package substrate 404, a remaining portion of the package substrate 404 that is not covered by the mold cap 408 may be used for the attachment of the heat spreader 416 to the package substrate 404. For example, the heat spreader 416 may have support walls that extend downward to the package substrate 404, as shown in FIG. 4E. Accordingly, various blocks of adhesive material 418 may be formed on the package substrate 404 not covered by the mold cap 408. The support walls of the heat spreader 416 may be attached to the package substrate 404 through the adhesive material 418. The adhesive material 418 can improve attachment of the heat spreader 416 to the semiconductor package 402, while not affecting the heat transfer from the semiconductor component 406 to the heat spreader 416.

After the various steps shown in FIGS. 4A to 4E, a semiconductor package assembly which combines a semiconductor package and a heat spreader can be obtained.

As can be seen from the methods shown in FIGS. 3A to 3D and FIGS. 4A to 4E, by laser activating the laser-activatable mold compound and transforming such compound to the conductive material, the method according to the embodiments of the present application can avoid complicated metal plating process of the seed layer. Also, the range and position of the activated mold compound can be accurately controlled, especially in regions not directly above the semiconductor component. Also, a thermal path between the heat spreader and the semiconductor component can be formed through the TIM layer, which renders an improved heat dissipation for the semiconductor package assembly so formed.

The discussion herein includes numerous illustrative figures that show various portions of a method for attaching a heat spreader to a semiconductor package and a semiconductor package assembly formed using such method. For illustrative clarity, such figures do not show all aspects of each example semiconductor package. Any of the example packages provided herein may share any or all characteristics with any or all other packages provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for attaching a heat spreader to a semiconductor package, the method comprising:
providing a semiconductor package, wherein the semiconductor package comprises a package substrate, a semiconductor component mounted on the package substrate and a mold cap formed on the package substrate and encapsulating the semiconductor component, and wherein the mold cap comprises a laser-activatable mold compound;
removing a portion of a thickness of the mold cap above the semiconductor component by laser ablation to form a cavity in the mold cap and transform the laser-activatable mold compound at an inner surface of the cavity to a conductive layer;
dispensing a thermal interface material (TIM) in the cavity to form on the conductive layer a TIM layer that protrudes from the mold cap; and
attaching the heater spreader to the semiconductor package at least through the TIM layer.

2. The method of claim 1, wherein the cavity in the mold cap extends across an entirety of the semiconductor component.

3. The method of claim 1, wherein the semiconductor package is a strip type package, and wherein attaching the heater spreader to the semiconductor package at least through the TIM layer further comprises:
dispensing an adhesive material on the mold cap; and
attaching the heater spreader onto the mold cap through the TIM layer and the adhesive material.

4. The method of claim 1, wherein the semiconductor package is a unit type package, and wherein attaching the heater spreader to the semiconductor package at least through the TIM layer further comprises:
dispensing an adhesive material on the package substrate; and
attaching the heater spreader onto the mold cap through the TIM layer and onto the package substrate through the adhesive material.

5. The method of claim 1, wherein the laser-activatable mold compound comprises a base material and additives of metal particles that are openable by laser.

6. A semiconductor package assembly, comprising:
a semiconductor package, wherein the semiconductor package comprises:
a package substrate,
a semiconductor component mounted on the package substrate, and
a mold cap formed on the package substrate and encapsulating the semiconductor component, wherein the mold cap comprises a laser-activatable mold compound, the mold cap comprises a cavity formed above the semiconductor component and having a conductive layer at its inter surface, and the cavity and the conductive layer are formed by laser ablation of the laser-activatable mold compound;
a thermal interface material (TIM) layer formed in the cavity of the mold cap and protruding from the mold cap; and
a heater spreader attached to the semiconductor package at least through the TIM layer.

7. The semiconductor package assembly of claim 6, wherein the cavity in the mold cap extends across an entirety of the semiconductor component.

8. The semiconductor package assembly of claim 6, wherein the cavity is formed such that a portion of a thickness of the mold cap remains above the semiconductor component and the TIM layer is not in direct contact with the semiconductor component.

9. The semiconductor package assembly of claim 6, wherein the semiconductor package is a strip type package, and the semiconductor package further comprises an adhesive material on the mold cap through which the heat spreader is attached to the semiconductor package.

10. The semiconductor package assembly of claim 6, wherein the semiconductor package is a unit type package, and the semiconductor package further comprises an adhesive material on the package substrate through which the heat spreader is attached to the semiconductor package.

11. The semiconductor package assembly of claim 6, wherein the laser-activatable mold compound comprises a base material and additives of metal particles that are openable by laser.
